(19) United States
(12) Patent Application Publication
(10) Pub. No.: US 2025/0199038 A1
(43) Pub. Date: Jun. 19, 2025

(54) UNDERVOLTAGE DETECTOR AND POWER SUPPLY SYSTEM INCLUDING THE SAME

(71) Applicant: SG MICRO CORP, Beijing (CN)

(72) Inventor: Huaishan Tian, Beijing (CN)

(21) Appl. No.: 18/847,679

(22) PCT Filed: Oct. 12, 2022
(86) PCT No.: PCT/CN2022/124809

§ 371 Date: Sep. 16, 2024

(30) Foreign Application Priority Data
Jun. 29, 2022 (CN) 202210744729.4

(51) Int. Cl. G01R 19/165; G01R 15/16; H02H 3/24; H02M 1/36

(52) U.S. Cl. CPC G01R 19/16519; G01R 15/16; H02H 3/24; H02M 1/36

(57) ABSTRACT

The present application discloses an undervoltage detector and a power supply system including the undervoltage detector. The undervoltage detector includes a switching capacitor circuit, a start-up control circuit, and a single-ended comparator circuit. The switching capacitor circuit samples a voltage to be detected and a reference voltage as time-division inputs and obtains a comparison result between the voltage to be detected and the reference voltage. The single-ended comparator circuit is obtains an undervoltage detection signal according to the comparison result. When the undervoltage detection signal is an invalid signal, the first transistor is in an off state. Thus, the present disclosure provides a circuit that does not have any power consumption while waiting for the undervoltage detection, which can greatly reduce the power consumption of the undervoltage detector, and is very suitable for being used as an ultra-low power undervoltage detector.

This application claims priority to the Chinese invention application Ser. No. 20/221,0744729.4, filed on Jun. 29, 2022, and entitled “UNDERVOLTAGE DETECTOR AND POWER SUPPLY SYSTEM INCLUDING THE SAME”, the content of which is incorporated herein by reference, including all of the specifications, claims, drawings and abstracts.

### TECHNICAL FIELD

The present disclosure relates to the technical field of power supply, and more particularly, to an undervoltage detector and a power supply system including the undervoltage detector.

### BACKGROUND

With the rapid development of 5G and the Internet of Things, various types of electronic devices are continued to be upgraded with increasing demand. Such electronic devices generally do not use power supply directly from the power grid, but instead converts an external high voltage into a precise and stable power supply voltage by a switching power supply or a linear voltage regulator. During the operation of regulated power supply, when a current is output to a load, an output voltage will decrease. A controller of the regulated power supply needs to control and increase conductivity of a power transistor or trigger charging of an output by an input for one time, when undervoltage is detected. Therefore, an undervoltage detection mechanism must be provided to determine whether the output voltage decreases to a preset reference.

Today, one commonly-used undervoltage detection method is to sample an output voltage with voltage-division resistors. Then, various types of comparators are used to determine whether the output voltage is undervoltage. Or, a comparator without a current before overvoltage is used for determination. The resistors and comparators in this circuit consume DC power during operation, which leads to an increase in the power consumption of the circuit and makes it difficult to achieve the power supply design with power consumption of less than several hundreds of nanoamperes. In some applications where power consumption is critical, especially in the field of IoT chips that require long hours of operation, the power consumption requirement of the chips is very high, which requires the power supply to have low power consumption. Therefore, it is necessary to design an undervoltage detector with ultra-low power consumption.

### SUMMARY

In view of this, it is an object of the present disclosure to provide a power supply system comprising an ultra-low power consumption undervoltage detector, which has static power consumption of zero.

According to an aspect of an embodiment of the present disclosure, there is provided an undervoltage detector comprising: a switching capacitor circuit, configured to sample a voltage to be detected and a reference voltage in time-division manner, and obtain a comparison result between the voltage to be detected and the reference voltage; a start-up control circuit coupled to a power supply voltage; a single-ended comparator circuit having a first transistor, a first terminal of the first transistor being coupled with the start-up control circuit, a control terminal of first transistor being coupled with an output of the switching capacitor circuit, and a second terminal of the first transistor being coupled with an output node that provides an undervoltage detection signal, wherein the single-ended comparator circuit is configured to obtain the undervoltage detection signal according to the comparison result, and the first transistor is in an off state when the undervoltage detection signal is an invalid signal.

Optionally, the start-up control circuit is configured to be enabled synchronously with the switching capacitor circuit to establish a supply path from the power supply voltage to the single-ended comparator circuit.

Optionally, the single-ended comparator circuit further comprises: a reference current source coupled between an output node that provides the undervoltage detection signal and ground.

Optionally, the switching capacitor circuit comprises: a first switch, having a first end coupled to the reference voltage and a second end coupled to a first node; a second switch, having a first end coupled to the voltage to be detected and a second end coupled to the first node; a first sampling capacitor, having a first end coupled to the first node, and a second end coupled to a second node which is an output of the switching capacitor circuit; and a fourth switch, having a first end coupled to the second node and a second end coupled to the output node, wherein the first switch and the fourth switch are turned on simultaneously, and the second switch is turned on in time-division manner with the first switch and the fourth switch.

Optionally, the start-up control circuit includes: a third switch, having a first end coupled to the first node, and a second end; a second sampling capacitor, having a first end coupled to the second end of the third switch, and a second end coupled to ground; and a second transistor, having a first terminal coupled to the power supply voltage, a control terminal coupled to the first end of the second sampling capacitor, and a second terminal which is an output of the start-up control circuit, wherein the third switch is turned on and off simultaneously with the first switch and the fourth switch.

Optionally, the first switch, the third switch, and the fourth switch are controlled by a first control signal, and the second switch is controlled by a second control signal that is different from the first control signal.

Optionally, the first control signal and the second control signal are two non-overlapping clock signals.

Optionally, the reference current source comprises: a first capacitor, having a first end coupled to the power supply voltage, and a second end; a third transistor, having a first terminal coupled to the power supply voltage, a control terminal coupled to the second end of the first capacitor, and a second terminal; a fifth switch, having a first end coupled to the control terminal of the third transistor, and a second end coupled to the second terminal of the third transistor; a sixth switch, having a first end coupled to the second terminal of the third transistor, and a second end; a constant current source, having a first end coupled to the sixth switch, and a second end coupled to ground; and a fourth transistor, having a first terminal coupled to the power supply voltage, a control terminal coupled to the second end of the first capacitor, and a second terminal that provides a reference current to the output node.

Optionally, the fifth switch and the sixth switch are turned on intermittently.

Optionally, the fifth switch and the sixth switch are controlled by a third control signal, and the third control signal is a clock signal.

Optionally, the first transistor is a P-type MOSFET and the second transistor is an N-type MOSFET.

According to another aspect of an embodiment of the present disclosure, there is provided a power supply system comprising the undervoltage detector described above.

In summary, the undervoltage detector according to the present disclosure includes a switching capacitor circuit, a start-up control circuit, and a single-ended comparator circuit. The switching capacitor circuit samples the voltage to be detected and the reference voltage as time-division inputs. The single-ended comparator circuit includes a first transistor with a first terminal of the first transistor coupled with the start-up control circuit, a control terminal coupled with an output of the switch capacitor circuit, and a second terminal coupled with an output node that provides an undervoltage detection signal. The single-ended comparator circuit is configured to obtain the undervoltage detection signal according to the comparison result, and when the undervoltage detection signal is an invalid signal, the first transistor is in an off state. Thus, the present disclosure provides a circuit that does not have any power consumption while waiting for the undervoltage detection, which can greatly reduce the power consumption of the undervoltage detector, and is very suitable for achieving an ultra-low power undervoltage detector.

Moreover, the start-up control circuit according to the embodiment of the present disclosure is enabled synchronously with the switching capacitor circuit to establish a supply path from the power supply voltage to the single-ended comparator circuit. Thus, the supply path from the power supply voltage to the single-ended comparator circuit can be cut off before the single-ended comparator circuit detects that undervoltage is reversed, thereby further reducing current consumption of the undervoltage detector.

Moreover, the reference current source of the undervoltage detector according to the present disclosure can further reduce power consumption of the circuit in a case that a reference current is generated by intermittently coupling with a constant current source during each time period. That is, the reference current is generated in a ticking manner, thereby realizing a power supply design with power consumption of less than several hundreds of nanoamperes.

### BRIEF DESCRIPTION OF THE DRAWINGS

The foregoing and other objects, features and advantages of the present disclosure will become clearer by the following description of embodiments of the present disclosure with reference to the accompanying drawings.

FIG. 1 shows a schematic circuit diagram of a fast-response power system according to an embodiment of the present disclosure;

FIG. 2 shows a schematic circuit diagram of a conventional undervoltage detector;

FIG. 3 shows a schematic circuit diagram of an undervoltage detector according to an embodiment of the present disclosure;

FIG. 4 shows a schematic circuit diagram of a reference current source according to an embodiment of the present disclosure.

### DETAILED DESCRIPTION

The present disclosure will be described in more detail below with reference to accompanying drawings. In various figures, the same elements are denoted by similar reference numerals. For the sake of clarity, various parts in the accompanying drawings are not drawn to scale. Moreover, certain well-known parts may not be shown in the figures.

Many specific details of the present disclosure, such as the structure, material, dimensions, treatment processes, and techniques of the components, are described below for more clear understanding of the present disclosure. However, as will be appreciated by those skilled in the art, the present disclosure may not be practiced in accordance with these specific details.

It should be understood that in the following description, the word “circuit” may include single or multiple combinations of hardware circuits, programmable circuits, state machine circuits, and/or components capable of storing instructions which are executed by a programmable circuitry. When a component or a circuit is said to be “connected” or “coupled” to another component, or a component/circuit is said to be “connected” or “coupled” between two nodes, it may be directly coupled or connected to the other component or with an intermediate component therebetween. The connection or coupling between the components may be physical, logical, or a combination thereof. Conversely, when the component is said to be “directly coupled” or “directly connected” to another component, it means that there is no intermediate component therebetween.

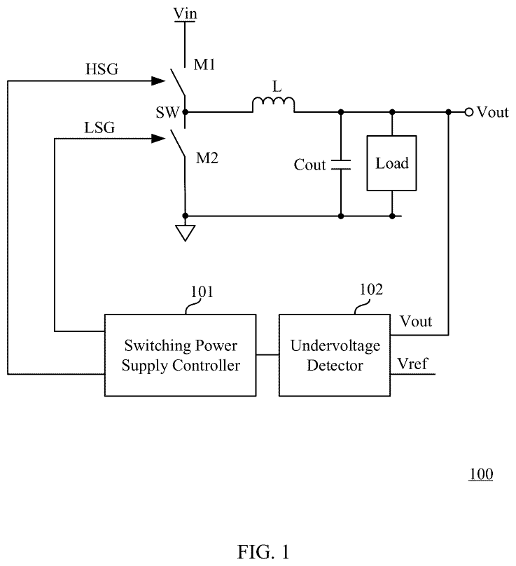

FIG. 1 shows a schematic circuit diagram of a fast-response power system according to an embodiment of the present disclosure. In this embodiment, a buck-type switching power supply is taken as an example, but the scope of application of the present disclosure is not limited to the buck-type switching power supply, but can also be applied to a boost-type switching power supply, a boost-buck-type switching power supply, a flyback switching power supply, a forward switching power supply or a low dropout linear regulator. As shown in FIG. 1, the power supply 100 includes a main switch M1 (also known as a high-side switch) and a synchronization switch M2 (also known as a low-side switch), an inductor L, an output capacitor Cout, a switching power supply controller 101, and an undervoltage detector 102.

Here, a first end of the main switch M1 is coupled to an input voltage Vin, a second end of the main switch M1 is coupled with a first end of the synchronization switch M2 at a switching node SW. A second end of the synchronization switch M2 is coupled to a ground GND. A first end of the inductor L is coupled to the switching node SW, and a second end is coupled to an output voltage Vout of the switching power supply. Here, the main switch M1 and the synchronization switch M2 can be any controllable semiconductor switching device, such as a metal oxide semiconductor field effect transistor (MOSFET), an insulated gate bipolar transistor (IGBT), or the like.

The switching power supply controller 101 provides a high-side driving signal HSG to the main switch M1 and a low-side driving signal LSG to the synchronization switch M2. The signals HSG and LSG are also referred to as switching control signals and are used to control switching of the electronic switches M1 and M2, respectively.

In this embodiment, the switching power supply controller 101 is illustrated in general form. However, the controller may be implemented as performing a voltage mode control, a current mode control, a constant on time (or constant frequency) control, etc. The controller may be configured as an analog or a digital controller.

Two inputs of the undervoltage detector 102 receive an output voltage Vout and a reference voltage Vref, respectively. An output of the undervoltage detector 102 is coupled to the switching power supply controller 101. When the output voltage Vout is greater than the reference voltage Vref, the output of the undervoltage detector 102 is logic low (or logic “0”). In such case, the switching power supply controller 101 turns off the main switch M1 and turns on the synchronization switch M2. When the power supplied to a load, the output voltage Vout also gradually decreases. Once the output voltage Vout is less than the reference voltage Vref, an output of the undervoltage detector 102 reverse to logic high (or logic “1”). The switching power supply controller 101 turns on the main switch M1 and turns off the synchronization switch M2 to charge the load after receiving a logic high signal from the undervoltage detector 102.

In other embodiments, the power supply 100 may also include a voltage-division resistor network, which divides the output voltage Vo and provides it to the undervoltage detector 102. The undervoltage detector 102 compares the voltage after division with the reference voltage Vref so that the switching power supply controller 101 controls and drives the main switch M1 and the synchronization switch M2. In order to achieve the power supply 100 with static power consumption of zero, it is necessary for the undervoltage detector 102 to have static power consumption of zero. That is, the undervoltage detector 102 only consumes current when an undervoltage reversion is detected, and has current consumption of zero while waiting for the undervoltage detection.

It can be understood that the power supply 100 according to this embodiment can also be implemented using a non-synchronization switching power supply. In the non-synchronization switching power supply, a rectification diode is used to replace the synchronization switch M2 in FIG. 1, which is not limited in this embodiment.

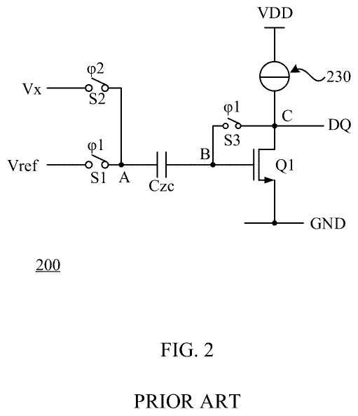

FIG. 2 shows a schematic circuit diagram of a conventional undervoltage detector. The undervoltage detector 200 includes a transistor Q1, switches S1-S3, a sampling capacitor Czc, and a reference current source 230. Here, one end of the switch S1 is coupled with a reference voltage Vref, one end of the switch S2 is coupled to a voltage Vx to be detected (for example, the output voltage Vout in FIG. 1). The other ends of the switches S1 and S2 are coupled with a first end of the sampling capacitor Czc. A second end of the sampling capacitor Czc is coupled with a gate of the transistor Q1. A source of the transistor Q1 is coupled to ground GND, a drain of the transistor Q1 is coupled with an output node DQ of the undervoltage detection signal DQ. The reference current source 230 is coupled between the output node of the undervoltage detection signal DQ and the power supply voltage VDD. Here, the switches S1 and S3 are controlled by a control signal φ1, the switch S2 is controlled by a control signal φ2. The control signals φ1 and φ2 are, for example, two non-overlapping clock signals.

The undervoltage detector 200 operates at two stages. The first stage is a sampling stage, in which the control signal φ1 is coupled to a high level so that the switches S1 and S3 are turned on, and the control signal φ2 is coupled to a low level so that the switch S2 is turned off. The sampling capacitor Czc samples the reference voltage Vref. The voltage at point A is equal to the reference voltage Vref, that is, VA=Vref. Due to an on state of the switch S3, the voltages at points B and C are pulled directly to an equal potential, that is, VB=VC. In such case, the constant current sources 230 with specially designed output capability and the transistor Q1 reach a linear balance state so that the signal DQ is maintained at a certain high potential. The second stage is a comparison stage. At this stage, the control signal φ1 is coupled to a low level so that the switches S1 and S3 are turned off, and the control signal φ2 is coupled to a high level so that the switch S2 is turned on. At this stage, the voltage at point A jumps from Vref at the sampling stage to the voltage Vx to be detected at the comparison stage. That is, a jump voltage at point A is ΔVA=Vx−Vref. Taking advantage of the fact that a voltage across a capacitor cannot change abruptly, the voltage at point B will also jump to the same value in view of an coupling effect of the sampling capacitor Czc, with a jump voltage at point B of ΔVB=Vx−Vref. The jump voltage ΔVB at point B is then amplified by the transistor Q1. The voltage VC at an output C of the comparator changes from a level at the sampling stage to a high level approaching VDD or a low level approaching 0, corresponding to a high level and a low level, respectively. When the comparator receives a voltage Vx to be detected that is less than the reference voltage Vref, that is, ΔVA is negative, the transistor Q1 is turned off or the degree of conduction is decreased. An output node C is pulled up to a higher level signal by the reference current source 230, and the undervoltage detector 200 maintains the undervoltage detection signal DQ in a valid state. Therefore, a high level or a low level at the output of the comparator is used to indicate whether the voltage Vx to be detected is greater than the reference voltage Vref or not with a high resolution.

The resolution of the comparator (i.e. a minimum discriminant voltage MDU) is determined by a minimum value of the difference ΔVA between the voltage Vx to be detected and the reference voltage Vref to cause the jump at the output between the high level and the low level, and depends on a DC gain of the comparator. In order to improve the DC gain or sensitivity of the undervoltage detector 200, a plurality of comparators may be connected in series as a plurality of stages to constitute the undervoltage detector 200 according to this embodiment.

In the conventional undervoltage detector 200, when the voltage Vx to be detected is higher than the reference voltage Vref, the gate of the N-type MOSFET transistor Q1 receives a voltage of a high level so that the N-type MOSFET transistor Q1 is always in an on state. This means that the circuit is always consuming power while waiting for undervoltage, causing high power consumption of the circuit. It is difficult to achieve a power supply design with power consumption less than several hundreds of nanoamperes.

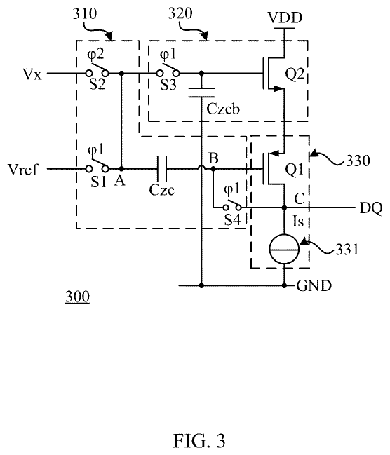

FIG. 3 shows a schematic circuit diagram of an undervoltage detector according to an embodiment of the present disclosure. As shown in FIG. 3, the undervoltage detector 300 according to this embodiment includes a switching capacitor circuit 310, a start-up control circuit 320, and a single-ended comparator circuit 330. Here, the switching capacitor circuit 310 has two inputs for receiving the voltage Vx to be detected and the reference voltage Vref, respectively, and an output. The switching capacitor circuit 310 is configured to sample the voltage Vx to be detected and the reference voltage Vref, respectively, and output a comparison result between the voltage Vx to be detected and the reference voltage Vref. A control terminal of the single-ended comparator circuit 330 is coupled with the output of the switching capacitor circuit 310 and is configured to obtain an undervoltage detection signal DQ according to the comparison result. The start-up control circuit 320 is coupled between an input of the single-ended comparator circuit 330 and a power supply voltage VDD, and is configured to be enabled synchronously with the switching capacitor circuit 310 to establish a supply path from the power supply voltage VDD to the single-ended comparator circuit 330. Thus, the supply path from the power supply voltage VDD to the single-ended comparator 330 may be cut off before undervoltage reversion is detected by the single-ended comparator circuit 330, which has an effect of eliminating static current before the circuit is started.

Specifically, the switching capacitor circuit 310 includes switches S1, S2, and S4 and a sampling capacitor Czc. One end of the switch S1 is coupled to the reference voltage Vref, and one end of the switch S2 is coupled to the voltage Vx to be detected. The other ends of the switches S1 and S2 are coupled with a first end of the sampling capacitor Czc at a node A. A second end of the sampling capacitor Czc is coupled with a node B, which is used as an output of the switching capacitor circuit 310. A first end of the switch S4 is coupled with the node B, and a second end of the switch S4 is coupled with an output node C of the undervoltage detection signal DQ.

The start-up control circuit 320 includes a switch S3, a sampling capacitor Czcb, and a transistor Q2. Here, a first end of the switch S3 is coupled with the node A, a second end of the switch S3 is coupled with a first end of the sampling capacitor Czcb. A second end of the sampling capacitor Czcb is coupled to ground GND. The transistor Q2 may be implemented, for example, using an N-type MOSFET. A drain of the transistor Q2 is coupled to the power supply voltage VDD, a gate of the transistor Q2 is coupled with a common node of the switch S3 and the sampling capacitor Czcb, and a source of the transistor Q2 is coupled with an input of the single-ended comparator circuit 330, as an output of the start-up control circuit 320.

The single-ended comparator circuit 330 includes a transistor Q1 and a reference current source 331. Here, the transistor Q1 may be implemented, for example, using a P-type MOSFET. A gate of the transistor Q1 is coupled with the node B, A source of the transistor Q1 is coupled with the source of the transistor Q2, and a drain of the transistor Q1 is coupled with the output node C. A first end of the reference current source 331 is coupled to the output node C, and a second end of the reference current source 331 is coupled to ground GND.

Here, the switches S1, S3 and S4 are controlled by the control signal φ1, the switch S2 is controlled by the control signal φ2. The control signals φ1 and φ2 are, for example, two non-overlapping clock signals.

The undervoltage detector 300 operates at two stages: the first stage is a sampling stage, during which the control signal φ1 is coupled to a high level so that the switches S1, S3 and S4 are turned on, the control signal φ2 is coupled to a low level so that the switch S2 is turned off. The reference voltage Vref establishes a bias voltage on the sampling capacitors Czc and Czcb for turning on the transistors Q1 and Q2. The voltage at point A and a gate voltage of the transistor Q2 are equal to the reference voltage Vref, that is, VA=Vref. Points B and C are pulled up to the same level because the switch S4 is turned on, that is, VB=VC. In such case, the output node C is at a level equal to the power supply voltage VDD minus a high level when the transistors Q1 and Q2 output a reference current Is. The second stage is a comparison stage. At this stage, the control signal φ1 is coupled to a low level so that the switches S1, S3 and S4 are turned off, the control signal φ2 is coupled to a high level, so that the switch S2 is turned on. At this stage, a voltage at point A jumps from the Vref at the sampling stage to the voltage Vx to be detected at the comparison stage. That is, a jump voltage at point A is ΔVA=Vx−Vref. Taking advantage of the fact that a voltage across a capacitor cannot change abruptly, the voltage at point B will also jump to the same value in view of an coupling effect of the sampling capacitor Czc, with a jump voltage at point B of ΔVB=Vx−Vref. The jump voltage at point B ΔVB is then amplified by the transistor Q1. The voltage VC at an output C of the comparator changes from a level at the sampling stage to a high level approaching VDD or a low level approaching 0, corresponding to a high level and a low level. When the comparator receives the voltage Vx to be detected that is greater than the reference voltage Vref, that is, when ΔVA is positive, the transistor Q1 is turned off or the degree of conduction is decreased. An output node C will be pulled down to a low level by the reference current source 331, and the undervoltage detector 300 outputs an undervoltage detection signal DQ of an invalid state. When the comparator receives the voltage Vx to be detected input that is less than the reference voltage Vref, that is, when the AA is negative, the transistor Q1 is turned on or has an enhanced conduction. An output node C is pulled up to a higher level, and the undervoltage detector 300 outputs an undervoltage detection signal of a valid state. Therefore, a high level or a low level at the output of the comparator is used to indicate whether the voltage Vx to be detected is greater than the reference voltage Vref or not with a high resolution.

The resolution of the comparator (i.e. a minimum discriminant voltage MDU) is determined by a minimum value of the difference ΔVA between the voltage Vx to be detected and the reference voltage Vref to cause the jump at the output between the high level and the low level, and depends on a DC gain of the comparator. In order to improve a DC gain or sensitivity of the undervoltage detector 300, a plurality of comparators may be connected in series as a plurality of stages to constitute the undervoltage detector 300 according to this embodiment.

As can be seen from the above description, in the undervoltage detector 300 according to the embodiment of the present disclosure, the transistor Q1 is always turned off or has a small degree of conduction at a stage during which the voltage to be detected Vx is higher than the reference voltage Vref, i.e. an undervoltage detection waiting phase, and the transistor Q1 will not be turned on until the undervoltage occurs. Therefore, this circuit can achieve extremely low static power consumption at the undervoltage detection waiting phase, which is very suitable for achieving the power supply design with power consumption of less than several hundreds of nanoamperes.

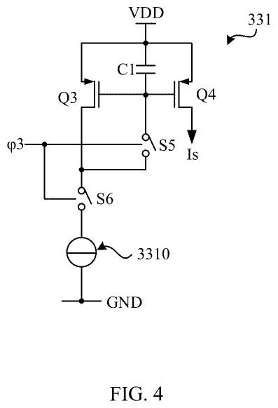

FIG. 4 shows a schematic circuit diagram of a reference current source according to an embodiment of the present disclosure. Referring to FIG. 4, the reference current source 331 includes transistors Q3 and Q4, switches S5 and S6, a constant current source 3310, and a capacitor C1. Here, a source of the transistor Q3 is coupled to the power supply voltage VDD, and a drain of the transistor Q3 is coupled with a first end of the constant current source 3310 via the switch S6. A second end of the constant current source 3310 is coupled to ground GND. A source of the transistor Q4 is coupled to the power supply voltage VDD, and a drain of the transistor Q4 is used as an output of the reference current Is. A first end of the capacitor C1 is coupled to the power supply VDD, and A second end of the capacitor C1 is coupled to gates of the transistors Q3 and Q4. A first end of the switch S5 is coupled with gates of the transistors Q3 and Q4, and a second end of the switch S5 is coupled to a drain of the transistor Q3. Here, the switches S5 and S6 are controlled by a control signal q3, which is, for example, a clock signal.

The reference current source 331 according to this embodiment generates a reference current Is in a ticking manner. That is, when the control signal 3 is coupled to a high level, the switches S5 and S6 are turned on to couple to the power supply voltage VDD, the capacitor C1 and the constant current source 3310. The gates of the P-type MOSFET transistors Q3 and Q4 are pulled down to ground GND, and the P-type MOSFET transistors Q3 and Q4 are turned on to generate the constant current output Is. Meanwhile, a bias voltage is stored on the capacitor C1 for turning on the P-type MOSFET transistors Q3 and Q4. When the control signal φ3 is coupled to a low level, the control switches S5 and S6 are turned off, but the bias voltage stored on the capacitor C1 continues to maintain the transistors Q3 and Q4 to be turned on, until the arrival of a high level of the control signal φ3 in a next cycle.

The constant current source 3310 according to the present embodiment may further reduce power consumption of the circuit in a case that a reference current Is is generated by intermittently coupling with the constant current source 3310 during each time period. That is, the reference current is generated in a ticking manner, which may be used as a circuit bias and a load in an ultra-low power circuit.

In summary, the undervoltage detector according to the present disclosure includes a switching capacitor circuit, a start-up control circuit, and a single-ended comparator circuit. The switching capacitor circuit samples the voltage to be detected and the reference voltage as time-division inputs. The single-ended comparator circuit includes a first transistor with a first terminal of the first transistor coupled with the start-up control circuit, a control terminal coupled with an output of the switch capacitor circuit, and a second terminal coupled with an output node that provides an undervoltage detection signal. The single-ended comparator circuit is configured to obtain the undervoltage detection signal according to the comparison result, and when the undervoltage detection signal is an invalid signal, the first transistor is in the off state. Thus, the present disclosure provides a circuit that does not have any power consumption while waiting for the undervoltage detection, which can greatly reduce the power consumption of the undervoltage detector, and is very suitable for achieving an ultra-low power undervoltage detector.

Moreover, the start-up control circuit according to the embodiment of the present disclosure is enabled synchronously with the switching capacitor circuit to establish a supply path from the power supply voltage to the single-ended comparator circuit. Thus, the supply path from the power supply voltage to the single-ended comparator circuit can be cut off before the single-ended comparator circuit detects that undervoltage is reversed, thereby further reducing current consumption of the undervoltage detector.

Moreover, the reference current source of the undervoltage detector according to the present disclosure can further reduce power consumption of the circuit in a case that a reference current is generated by intermittently coupling with a constant current source during various time periods. That is, the reference current is generated in a ticking manner, thereby realizing a power supply design with power consumption of less than several hundreds of nanoamperes.

It will be appreciated by those of ordinary skill in the art that the words “during”, “when”, and “while” used herein in connection with circuit operation are not strict terms for actions that occur immediately at the beginning of a start action, but that there may be some small but reasonable one or more delays after a reaction action initiated by a start action, such as various transmission delays, etc. As used herein, the word “approximately” or “substantially” means an element has a parameter that is expected to approximate the declared value or location. However, as is well known in the art, there are always minor deviations that make it difficult to have the value or position to be strictly the declared value. It has been properly determined in the art that a deviation of at least ten percent (10%) is a reasonable deviation from the precise desired target described (for a doping concentration of semiconductor, at least twenty percent (20%)). When a signal is described in the context of a state, an actual voltage value or logic state of the signal (e.g. “1” or “0”) depends on whether positive or negative logic is used.

It should also be noted that in this description, relational terms such as first and second are merely used to distinguish one entity or operation from another, and do not necessarily require or imply that there is any such actual relationship or sequence among these entities or operations. Furthermore, the word “include”, “contain”, or any other variation thereof is intended to cover non-exclusive inclusion, so that a process, method, article, or device including a series of elements includes not only those elements, but other elements that are not explicitly listed or elements inherent to such process, method, article, or device. In the absence of further limitations, elements defined by the phrase “comprises a . . . ” do not exclude the presence of additional identical elements in the process, method, article, or device that includes the elements.

In accordance with the embodiments of the present disclosure, such as described above, these embodiments do not describe all the details in detail, nor do they limit the invention to the specific embodiments described. Obviously, a lot of modifications and changes can be made based on the above description. These embodiments are selected and specifically described in this specification in order to better explain the principles and practical applications of the present disclosure, so that those skilled in the art can make good use of the present disclosure and its modifications on the basis of the present disclosure. The present disclosure is limited only by the claims and their full scope and equivalents.

1. An undervoltage detector, comprising:
a switching capacitor circuit, configured to sample a voltage to be detected and a reference voltage in time-division manner, and obtain a comparison result between the voltage to be detected and the reference voltage;
a start-up control circuit coupled to a power supply voltage;
a single-ended comparator circuit having a first transistor, a first terminal of the first transistor being coupled with the start-up control circuit, a control terminal of first transistor being coupled with an output of the switching capacitor circuit, and a second terminal of the first transistor being coupled with an output node that provides an undervoltage detection signal,
wherein the single-ended comparator circuit is configured to obtain the undervoltage detection signal according to the comparison result, and the first transistor is in an off state when the undervoltage detection signal is an invalid signal.

2. The undervoltage detector according to claim 1, wherein the start-up control circuit is configured to be enabled synchronously with the switching capacitor circuit to establish a supply path from the power supply voltage to the single-ended comparator circuit.

3. The undervoltage detector according to claim 1, wherein the single-ended comparator circuit further comprises:
a reference current source coupled between the output node that provides the undervoltage detection signal and ground.

4. The undervoltage detector according to claim 1, wherein the switching capacitor circuit comprises:
a first switch, having a first end coupled to the reference voltage and a second end coupled to a first node;
a second switch, having a first end coupled to the voltage to be detected and a second end coupled to the first node;
a first sampling capacitor, having a first end coupled to the first node, and a second end coupled to a second node which is an output of the switching capacitor circuit; and
a fourth switch, having a first end coupled to the second node and a second end coupled to the output node,
wherein the first switch and the fourth switch are turned on simultaneously, and the second switch is turned on in time-division manner with the first switch and the fourth switch.

5. The undervoltage detector according to claim 4, wherein the start-up control circuit comprises:
a third switch, having a first end coupled to the first node, and a second end;
a second sampling capacitor, having a first end coupled to the second end of the third switch, and a second end coupled to ground; and
a second transistor, having a first terminal coupled to the power supply voltage, a control terminal coupled to the first end of the second sampling capacitor, and a second terminal which is an output of the start-up control circuit,
wherein the third switch is turned on and off simultaneously with the first switch and the fourth switch.

6. The undervoltage detector according to claim 5, wherein the first switch, the third switch, and the fourth switch are controlled by a first control signal, and the second switch is controlled by a second control signal different from the first control signal.

7. The undervoltage detector according to claim 6, wherein the first control signal and the second control signal are two non-overlapping clock signals.

8. The undervoltage detector according to claim 3, wherein the reference current source comprises:
a first capacitor, having a first end coupled to the power supply voltage, and a second end;
a third transistor, having a first terminal coupled to the power supply voltage, a control terminal coupled to the second end of the first capacitor, and a second terminal;
a fifth switch, having a first end coupled to the control terminal of the third transistor, and a second end coupled to the second terminal of the third transistor;
a sixth switch, having a first end coupled to the second terminal of the third transistor, and a second end;
a constant current source, having a first end coupled to the sixth switch, and a second end coupled to ground; and
a fourth transistor, having a first terminal coupled to the power supply voltage, a control terminal coupled to the second end of the first capacitor, and a second terminal that provides a reference current to the output node.

9. The undervoltage detector according to claim 7, wherein the fifth switch and the sixth switch are turned on intermittently.

10. The undervoltage detector according to claim 8, wherein the fifth switch and the sixth switch are controlled by a third control signal, and the third control signal is a clock signal.

11. The undervoltage detector according to claim 5, wherein the first transistor is a P-type MOSFET and the second transistor is an N-type MOSFET.

12. A power supply system, comprising an undervoltage detector according to claim 1.
